(19) United States
(12) Patent Application Publication
(10) Pub. No.: US 2025/0380557 A1
(43) Pub. Date: Dec. 11, 2025

(54) DISPLAY DEVICE HAVING AN ARRANGEMENT OF A LIGHT BLOCKING LAYER AND COLOR FILTERS

(71) Applicant: SAMSUNG DISPLAY CO., LTD., YONGIN-SI (KR)

(72) Inventors: Se Hee KIM, Yongin-si (KR); Seung Han KIM, Yongin-si (KR); Sang Min HONG, Yongin-si (KR)

(21) Appl. No.: 19/022,571

(22) Filed: Jan. 15, 2025

(30) Foreign Application Priority Data
Jun. 7, 2024 (KR) 10-2024-0074139

(51) Int. Cl. H10H 29/855; H10H 29/85

(52) U.S. Cl. CPC H10H 29/8552; H10H 29/8517

(57) ABSTRACT

A display device includes a display area in which a first pixel and a second pixel are disposed. Each of the first pixel and the second pixel includes first to third light emission areas. A first light blocking layer is disposed in the display area and corresponds to the second pixel. A plurality of color filters are disposed on the first light blocking layer. A second light blocking layer is disposed on the color filter. The second light blocking layer includes a plurality of holes overlapping the first to third light emission areas of each of the first pixel and the second pixel. The first light blocking layer includes first to third light blocking patterns surrounding the first to third light emission areas, respectively.

### CROSS-REFERENCE TO RELATED APPLICATION

This application claims priority under 35 U.S.C. § 119 to Korean Patent Application No. 10-2024-0074139 filed on Jun. 7, 2024, in the Korean Intellectual Property Office, the contents of which are herein incorporated by reference in its entirety.

### TECHNICAL FIELD

The present disclosure relates to a display device and, more specifically, to a display device having an arrangement of a light blocking layer and color filters.

### DISCUSSION OF THE RELATED ART

As technology advances, the demand for display devices capable of presenting images in various forms has grown significantly. These devices are now integrated into a wide range of electronic products, including smart phones, digital cameras, laptop computers, navigation systems, and smart televisions.

Modern display devices are often flat panel types, such as liquid crystal displays (LCDs), a field emission displays, and organic light emitting diode (OLED) displays. In particular, light-emitting displays utilize self-emissive elements, allowing each pixel in the display panel to emit light independently. This eliminates the need for a backlight, enabling the device to display images more efficiently and with improved contrast.

### SUMMARY

A display device includes a display area in which a first pixel and a second pixel are disposed. Each of the first pixel and the second pixel include first to third light emission areas. A first light blocking layer is disposed in the display area and corresponds to the second pixel. A plurality of color filters is disposed on the first light blocking layer. A second light blocking layer is disposed on the plurality of color filters, the second light blocking layer including a plurality of holes respectively overlapping the first to third light emission areas of each of the first pixel and the second pixel. The first light blocking layer includes first to third light blocking patterns surrounding the first to third light emission areas, respectively.

The first light blocking layer may be omitted from the first pixel.

The plurality of holes of the second light blocking layer may include, first to third holes surrounding the first to third light emission areas of the first pixel, respectively, and fourth to sixth holes surrounding the first to third light emission areas of the second pixel, respectively.

A distance between the fourth hole and the first light emission area of the second pixel may be a first distance. A distance between the fifth hole and the second light emission area of the second pixel may be a second distance. A distance between the sixth hole and the third light emission area of the second pixel may be a third distance. Each of the first distance, the second distance, and the third distance may be different from one another.

A planar size of the first light emission area may be larger than a planar size of the second light emission area. A planar size of the third light emission area may be larger than the planar size of the first light emission area. The third distance may be smaller than the first distance. The first distance may be smaller than the second distance.

A distance between the first light blocking pattern and the first light emission area of the second pixel may be a fourth distance. A distance between the second light blocking pattern and the second light emission area of the second pixel may be a fifth distance. A distance between the third light blocking pattern and the third light emission area of the second pixel may be a sixth distance. Each of the fourth distance, the fifth distance, and the sixth distance may be different from one another.

IA planar size of the first light emission area may be larger than a planar size of the second light emission area. A planar size of the third light emission area may be larger than the planar size of the first light emission area. The sixth distance may be smaller than the fourth distance. The fourth distance may be smaller than the fifth distance.

A distance between the first hole and the first light emission area of the first pixel may be a seventh distance. A distance between the second hole and the second light emission area of the first pixel may be an eighth distance. A distance between the third hole and the third light emission area of the first pixel may be a ninth distance. Each of the seventh distance, the eight distance, and the ninth distance may be the same as one another.

A distance between the first hole and the first light emission area of the first pixel may be greater than a distance between the fourth hole and the first light emission area of the second pixel. A distance between the second hole and the second light emission area of the first pixel may be greater than a distance between the fifth hole and the second light emission area of the second pixel. A distance between the third hole and the third light emission area of the first pixel may be greater than a distance between the sixth hole and the third light emission area of the second pixel.

A distance between an inner side of the first light blocking pattern and the fourth hole may be a tenth distance. A distance between an inner side of the second light blocking pattern and the fifth hole may be an eleventh distance. A distance between an inner side of the third light blocking pattern and the sixth hole may be a twelfth distance. Each of the tenth distance, the eleventh distance, and the twelfth distance may be the same as one another.

At least a portion of the first to third light blocking patterns may overlap the fourth to sixth holes, respectively.

Both the first pixel and the second pixel may emit light in a first light emitting mode, the second pixel may emit light in a second light emitting mode, and the first pixel might not emit light in the second light emitting mode.

The color filter may cover the first light blocking layer.

Each of the first to third light blocking patterns may have a ring shape.

A display device including a first pixel including first to third light emission areas and a second pixel including fourth to sixth light emission areas. Each of the first pixel and the second pixel includes a plurality of light emitting elements disposed in the first to sixth light emission areas, respectively, a color filter layer disposed on the plurality of light emitting elements, the color filter layer including a plurality of color filters covering the first to sixth light emission areas, and a second light blocking layer disposed on the color filter layer, the second light blocking layer including first to sixth holes that overlap the first to sixth light emission areas, respectively. The second pixel further includes a first light blocking layer disposed between the plurality of light emitting elements and the color filter layer, including first to third light blocking patterns surrounding the fourth to sixth light emission areas, respectively.

The first light blocking layer may be omitted from the first pixel.

A planar size of the first light emission area may be larger than a planar size of the second light emission area, a planar size of the third light emission area may be larger than the planar size of the first light emission area. A planar size of the fourth light emission area may be larger than a planar size of the fifth light emission area. A planar size of the sixth light emission area may be larger than the planar size of the fourth light emission area.

A distance between the sixth hole and the sixth light emission area may be smaller than a distance between the fourth hole and the fourth light emission area. A distance between the fourth hole and the fourth light emission area may be smaller than a distance between the fifth hole and the fifth light emission area.

A distance between the third light blocking pattern and the sixth light emission area may be smaller than a distance between the first light blocking pattern and the fourth light emission area. The distance between the first light blocking pattern and the fourth light emission area may be smaller than a distance between the second light blocking pattern and the fifth light emission area.

A distance between the first hole and the first light emission area may be a thirteenth distance. A distance between the second hole and the second light emission area may be a fourteenth distance. A distance between the third hole and the third light emission area may be a fifteenth distance. The thirteenth distance, the fourteenth distance, and the fifteenth distance are the same as one another.

A distance between the first hole and the first light emission area may be greater than a distance between the fourth hole and the fourth light emission area. A distance between the second hole and the second light emission area may be greater than a distance between the fifth hole and the fifth light emission area. A distance between the third hole and the third light emission area may be greater than a distance between the sixth hole and the sixth light emission area.

A distance between an inner side of the first light blocking pattern and the fourth hole may be a sixteenth distance. A distance between an inner side of the second light blocking pattern and the fifth hole may be a seventeenth distance. A distance between an inner side of the third light blocking pattern and the sixth hole may be an eighteenth distance. Each of the sixteenth distance, the seventeenth distance, and the eighteenth distance may be the same as one another.

An electronic device includes a housing and a display panel disposed on the housing. The display panel includes a display area in which a first pixel and a second pixel are disposed, each of the first pixel and the second pixel including first to third light emission areas. A first light blocking layer is disposed in the display area and corresponding to the second pixel. A plurality of color filters are disposed on the first light blocking layer. A second light blocking layer is disposed on the plurality of color filters. The second light blocking layer includes a plurality of holes respectively overlapping the first to third light emission areas of each of the first pixel and the second pixel. The first light blocking layer includes first to third light blocking patterns surrounding the first to third light emission areas, respectively.

The electronic device may further include an optical device disposed within the display panel, the optical device configured to emit and/or sense light.

The optical device may be a proximity sensor, an illuminance sensor, a camera, a fingerprint reader, and/or a dot projector.

The display panel may be a bendable and the housing that includes a hinge mechanism for accommodating the bendable display panel.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an electronic device according to an embodiment;

FIG. 2 is a perspective view illustrating a display device included in an electronic device according to an embodiment;

FIG. 3 is a cross-sectional view illustrating a display device according to an embodiment;

FIG. 4 is a plan view illustrating a light emission area and a touch electrode in a display area of a display device according to an embodiment;

FIG. 5 is a plan view illustrating a light emitting pixel depending on a light emitting mode of a display device according to an embodiment;

FIG. 6 is a plan view illustrating a light emission area and a first light blocking layer in a display area of a display device according to an embodiment;

FIG. 7 is a plan view illustrating a light emission area and a color filter layer in a display area of a display device according to an embodiment;

FIG. 8 is a plan view illustrating a light emission area and a second light blocking layer in a display area of a display device according to an embodiment;

FIG. 9 is a plan view illustrating a light emission area, a first light blocking layer, a color filter layer and a second light blocking layer in a display area of a display device according to an embodiment;

FIG. 10 is a cross-sectional view taken along line X1-X1′ of FIG. 9;

FIG. 11 is a cross-sectional view taken along line X2-X2′ of FIG. 9;

FIG. 12 is a plan view illustrating a first pixel of a display device according to an embodiment;

FIG. 13 is a plan view illustrating a second pixel of a display device according to an embodiment;

FIG. 14 is a graph illustrating a color coordinate system indicating WAD characteristics of a display device according to a comparative embodiment; and

FIG. 15 is a graph illustrating a color coordinate system indicating WAD characteristics of a display device according to an embodiment.

### DETAILED DESCRIPTION OF THE DISCLOSURE

Embodiments of the present disclosure will now be described more fully hereinafter with reference to the accompanying drawings. This invention may, however, be embodied in different forms and should not necessarily be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers may indicate the same components throughout the specification and the drawings.

Hereinafter, embodiments of the present disclosure will be described in detail with reference to the accompanying drawings.

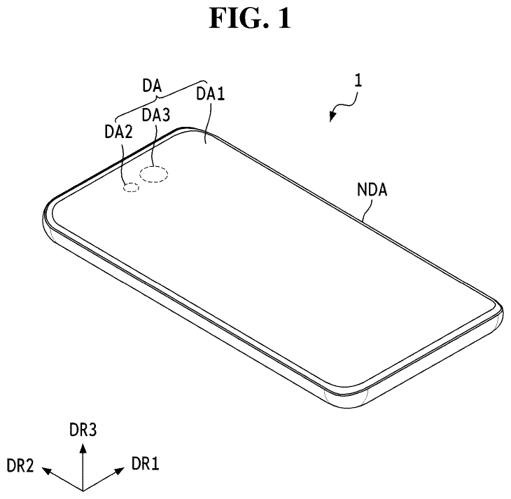

FIG. 1 is a schematic perspective view illustrating an electronic device according to an embodiment.

Referring to FIG. 1, an electronic device 1 displays a moving image and/or a still image. The electronic device 1 may be referred to as all electronic devices that provide a display screen. For example, a television, a laptop computer, a computer monitor, a digital billboard, an Internet of Things device, a mobile phone, a smart phone, a tablet computer, an electronic watch, smart glasses, a smart watch, a watch phone, a head mounted display, a mobile communication terminal, an electronic diary, an electronic book, a portable multimedia player (PMP), a navigation system, a portable game console, a digital camera, a camcorder and the like, which provide a display screen, may be included in the electronic device 1.

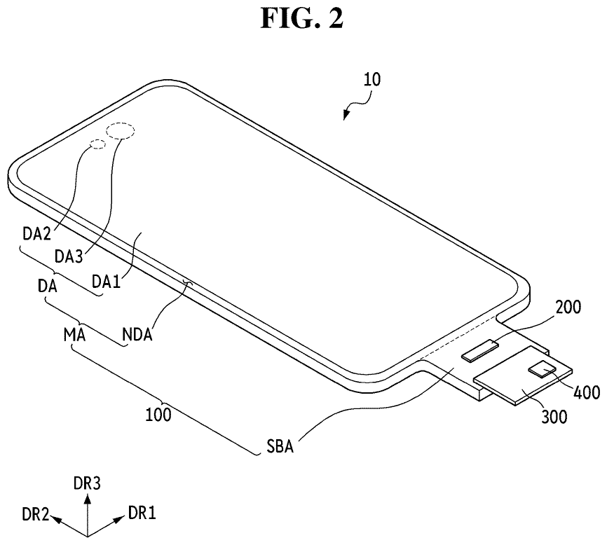

Examples of the electronic device 1 may include a display device 10 (see FIG. 2) that provides a display screen. Examples of the display device may include an inorganic light emitting diode display device, an organic light emitting diode (OLED) display device, a quantum dot light emitting display device, a plasma display device, and a field emission display device. The following description will be based on the example of an inorganic light emitting diode (LED) display device, but the present disclosure is not necessarily limited thereto, and another type of display device may be used.

Various modifications may be made in a shape of the electronic device 1. For example, the electronic device 1 may have a shape such as a rectangle that is longer in the width-direction, a rectangle that is longer in the length-direction, a square, a rounded rectangle (a rectangle that has rounded corners/vertexes), other types of polygon shapes, and/or a circle, oval, or other rounded shape. A shape of a display area DA of the electronic device 1 may also be similar to an overall shape of the electronic device 1. A rectangular electronic device 1, in which a length in a second direction DR2 is longer than a length in a first direction DR1, is illustrated in FIG. 1.

In the drawing, the first and second directions DR1 and DR2 are horizontal directions and cross each other. For example, the first direction DR1 and the second direction DR2 may be orthogonal to each other. Also, a third direction DR3 crosses the first and second directions DR1 and DR2, and may be, for example, a vertical direction. Unless defined otherwise, in the present disclosure, directions indicated by arrows in the first to third directions DR1, DR2 and DR3 may be referred to as one side, and their opposite directions may be referred to as the other side. Also, in the present disclosure, “upper”, “upper side”, “upper portion”, “top” and “upper surface” refer to a direction toward which the arrow in the third direction DR3 is directed based on the drawing, and “lower”, “lower side”, “lower portion”, “bottom” and “lower surface” refer to an opposite direction of the direction toward which the arrow in the third direction DR3 is directed based on the drawing.

The electronic device 1 may include a display area DA and a non-display area NDA. The display area DA is an area in which an image may be displayed, and the non-display area NDA is an area in which an image is not displayed. The display area DA may be referred to as an active area, and the non-display area NDA may be referred to as a non-active area. The display area DA may generally occupy the center of the electronic device 1. The non-display area NDA may be proximate to the display area DA on one, two, three, or more sides thereof.

The display area DA may include a first display area DA1, a second display area DA2, and a third display area DA3. The second display area DA2 and the third display area DA3 are areas in which components for adding various functions to the electronic device 1 are disposed, and may correspond to component areas.

FIG. 2 is a perspective view illustrating a display device included in an electronic device according to an embodiment.

Referring to FIG. 2 in addition to what is shown in FIG. 1, the electronic device 1, according to an embodiment, may include a display device 10. The display device 10 may provide a screen. The display device 10 may have a planar shape similar to that of the electronic device 1. For example, the display panel 100 may have a planar shape similar to a rectangular shape having a pair of short sides extending in the first direction DR1 and a pair of long sides extending in the second direction DR2. A corner at which a short side extending in the first direction DR1 meets a long side extending in the second direction DR2 may be rounded to have a desired degree of curvature, but may be formed at a right angle, without necessarily being limited thereto. The planar shape of the display device 10 may have another polygonal shape or a shape similar to a circular shape or an oval shape without necessarily being limited to the rectangular shape.

The display device 10 may include a display panel 100, a display driver 200, a circuit board 300 and a touch driver 400.

The display panel 100 may include a main area MA and a sub-area SBA.

The main area MA may include a display area DA including pixels for displaying an image and a non-display area NDA disposed proximate to the display area DA. The display area DA may be disposed at the center of the main area MA, and the non-display area NDA may surround the display area DA. The display area DA may include a first display area DA1, a second display area DA2, and a third display area DA3. The display area DA may emit light from a plurality of light emission areas or a plurality of opening areas. For example, the display panel 100 may include a pixel circuit including switching elements, a pixel defining layer defining a light emission area or an opening area, and a self-light emitting element.

For example, the self-light emitting element may include at least one of an organic light emitting diode including an organic light emitting layer, a quantum dot light emitting diode (LED) including a quantum dot light emitting layer, an inorganic light emitting diode (inorganic LED) including an inorganic semiconductor, or a micro light emitting diode (micro LED), but is not necessarily limited thereto.

The non-display area NDA may be an outer area of the display area DA. The non-display area NDA may be defined as an edge area of the main area MA of the display panel 100. The non-display area NDA may include a gate driver supplying gate signals to gate lines, and fan-out lines connecting the display driver 20 with the display area DA.

The sub-area SBA may be an area extended from one side of the main area MA. The sub-area SBA may include a flexible material capable of being subjected to bending, folding, rolling and the like, to a noticeable degree without cracking or otherwise sustaining damage. For example, when the sub-area SBA is bent, the sub-area SBA may overlap the main area MA in a thickness direction (e.g., the third direction DR3). The sub-area SBA may include a pad portion connected to the display driver 200 and the circuit board 300. In an embodiment, the sub-area SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to a power line, and may supply a gate control signal to a gate driver. The display driver 200 may include an integrated circuit (IC), and may be packaged on the display panel 100 by a chip on glass (COG) mode, a chip on plastic (COP) mode or an ultrasonic bonding mode. For example, the display driver 200 may be disposed in the sub-area SBA, and may overlap the main area MA in the thickness direction by bending of the sub-area SBA. For example, the display driver 200 may be packaged on the circuit board 300.

The circuit board 300 may be attached onto the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be packaged on the circuit board 300. The touch driver 400 may be connected to a touch sensor of the display panel 100. The touch driver 400 may supply a touch driving signal to a plurality of touch electrodes of the touch sensor, and may sense a change amount of capacitance between the plurality of touch electrodes. For example, the touch driving signal may be a pulse signal having a predetermined frequency. The touch driver 400 may calculate whether to input and input coordinates based on the change amount of capacitance between the plurality of touch electrodes. The touch driver 400 may include an integrated circuit (IC).

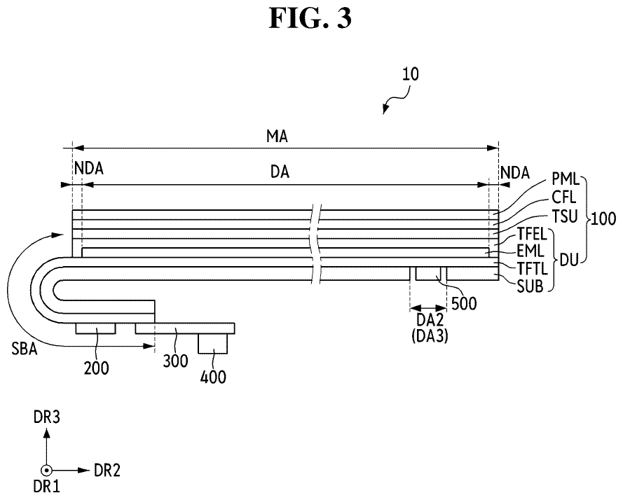

FIG. 3 is a cross-sectional view illustrating a display device according to an embodiment. FIG. 3 illustrates a state in which the sub-area SBA of the display panel 100 is bent in the display device 10 of FIG. 2.

Referring to FIG. 3, the display panel 100 may include a display layer DU, a touch sensing layer TSU, a color filter layer CFL and a light blocking layer PML. The display layer DU may include a substrate SUB, a thin film transistor layer TFTL, a light emitting element layer EML and an encapsulation layer TFEL.

The substrate SUB may be a base substrate or a base. The substrate SUB may be a flexible substrate capable of being subjected to bending, folding, rolling or the like, to a noticeable degree without cracking or otherwise sustaining damage. For example, the substrate SUB may include a polymer resin such as polyimide (PI), but is not necessarily limited thereto. In an embodiment, the substrate SUB may include a glass or a metal.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines connecting the display driver 200 to the data lines, and lead lines connecting the display driver 200 to the pad portion. Each of the thin film transistors may include a semiconductor area, a source electrode, a drain electrode and a gate electrode. For example, when the gate driver is formed on one side of the non-display area NDA of the display panel 100, the gate driver may include thin film transistors.

The thin film transistor layer TFTL may be disposed in the display area DA, the non-display area NDA and the sub-area SBA. The thin film transistors, the gate lines, the data lines and the power lines of the pixels of the thin film transistor layer TFTL may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements that include a first electrode, a second electrode, and a light emitting layer that is configured to emit light, and a pixel defining layer for defining pixels. The plurality of light emitting elements of the light emitting element layer EML may be disposed in the display area DA.

In an embodiment, the light emitting layer may be an organic light emitting layer that includes an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer so as to emit light.

In an embodiment, the light emitting element may include a quantum dot light emitting diode including a quantum dot light emitting layer, an inorganic light emitting diode including an inorganic semiconductor, or a micro light emitting diode.

The encapsulation layer TFEL may cover an upper surface and a side of the light emitting element layer EML, and may protect the light emitting element layer EML. The encapsulation layer TFEL may include at least one inorganic layer and at least one organic layer to encapsulate the light emitting element layer EML.

The touch sensing layer TSU may be disposed on the encapsulation layer TFEL. The touch sensing layer TSU may include a plurality of touch electrodes for sensing a user's touch in a capacitance manner, and touch lines for connecting the touch electrodes with the touch driver 400. For example, the touch sensing layer TSU may sense a user's touch in a mutual capacitance manner or a self-capacitance manner.

In an embodiment, the touch sensing layer TSU may be disposed on a separate substrate disposed on the display layer DU. In this case, the substrate supporting the touch sensing layer TSU may be a base for encapsulating the display layer DU.

The plurality of touch electrodes of the touch sensing layer TSU may be disposed in a touch sensor area that overlaps the display area DA. The touch lines of the touch sensing layer TSU may be disposed in a touch peripheral area that overlaps the non-display area NDA.

The color filter layer CFL may be disposed on the touch sensing layer TSU. The color filter layer CFL may include a plurality of color filters respectively corresponding to the plurality of light emission areas. Each of the color filters may selectively transmit light of a specific wavelength and may block or absorb light of another wavelength. The color filter layer CFL may absorb a portion of ambient light incident from outside of the display device 10 to reduce reflective light due to external light. Therefore, the color filter layer CFL may prevent color distortion due to reflection of the external light.

As the color filter layer CFL is directly disposed on the touch sensing layer TSU, the display device 10 might not need a separate substrate for the color filter layer CFL. Therefore, a thickness of the display device 10 may be relatively small.

The light blocking layer PML may be disposed on the color filter layer CFL. The light blocking layer PML may include light blocking patterns corresponding to specific pixels of the display layer DU. The display device 10 may further include a light blocking layer PML to control visibility at a specific viewing angle and provide a privacy protection mode to a user.

In some embodiments, the display device 10 may further include an optical device 500. The optical device 500 may be disposed in the second display area DA2 or the third display area DA3. The optical device 500 may emit or receive light of an infrared, ultraviolet or visible band. For example, the optical device 500 may be a proximity sensor, an illuminance sensor, or an optical sensor that senses light incident on the display device 10, such as and a camera sensor or an image sensor.

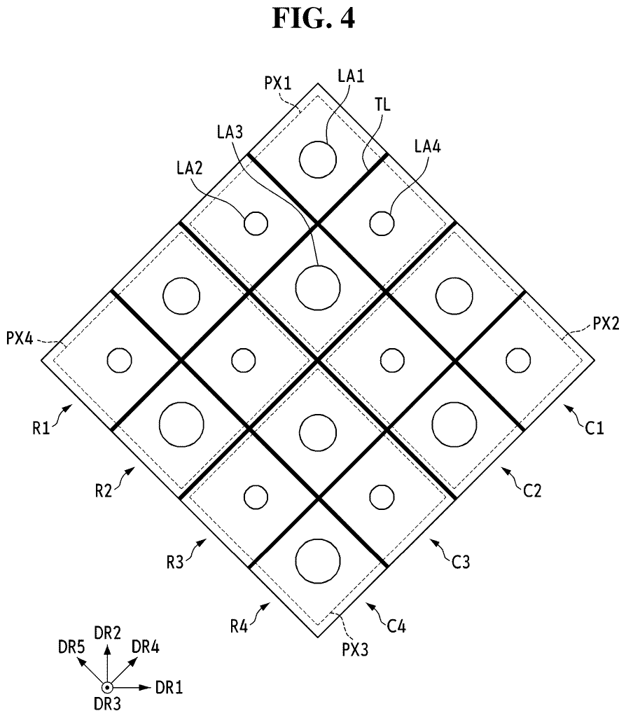

FIG. 4 is a plan view illustrating a light emission area and a touch electrode in a display area of a display device according to an embodiment.

Referring to FIG. 4, the display device 10 may include a plurality of pixels PX1, PX2, PX3 and PX4 disposed in the display area DA. The plurality of pixels PX1, PX2, PX3 and PX4 may be arranged in fourth and fifth directions DR4 and DR5, which are diagonal directions between the first and second directions DR1 and DR2. For example, the first pixel PX1 and the second pixel PX2 may be adjacent to each other in the fifth direction DR5, and the second pixel PX2 and the third pixel PX3 may be adjacent to each other in the fourth direction DR4. The third pixel PX3 and the fourth pixel PX4 may be adjacent to each other in the fifth direction DR5. The plurality of pixels PX1, PX2, PX3 and PX4 may be repeatedly disposed in an array of FIG. 4 over an entire surface of the display area DA.

Each of the plurality of pixels PX1. PX2, PX3 and PX4 may include a plurality of light emission areas LA1, LA2, LA3 and LA4. For example, each of the plurality of pixels PX1, PX2, PX3 and PX4 may include a first light emission area LA1, a second light emission area LA2, a third light emission area LA3, and a fourth light emission area LA4, but is not necessarily limited thereto. Various modifications may be made in the number of light emission areas LA1, LA2, LA3 and LA4 disposed in the pixels PX1, PX2, PX3 and PX4.

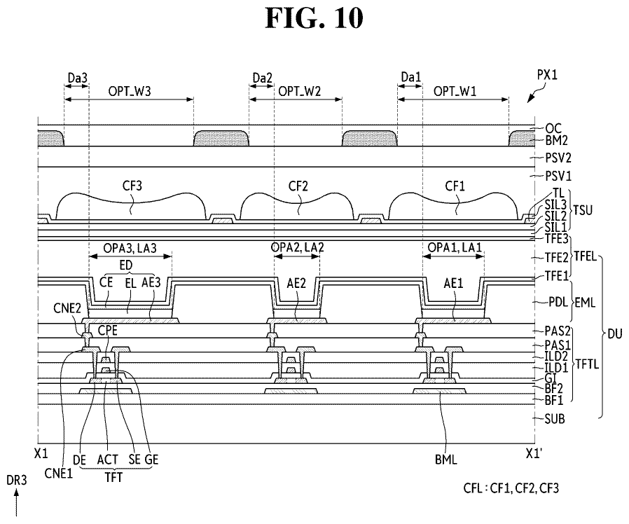

One pixel PX1, PX2, PX3 or PX4 may include one or more light emitting elements ED (see FIG. 10). In some embodiments, one or more light emitting elements ED (see FIG. 10) included in one pixel PX1, PX2, PX3 or PX4 may emit light of the same color or their respective colors different from one another. For example, the light emitting element ED (see FIG. 10) including the first light emission area LA1 may emit first light of a red color, the light emitting element ED (see FIG. 10) including the second light emission area LA2 may emit second light of a green color, and the light emitting element ED (see FIG. 10) including the third light emission area LA3 may emit third light of a blue color. Also, the light emitting element ED (see FIG. 10) including the fourth light emission area LA4 may emit the second light of a green color. However, the present disclosure is not necessarily limited to these examples.

The light emission areas LA1, LA2, LA3 and LA4 may emit light of various colors. For example, the first light emission area LA1 may emit the first light of a red color, the second light emission area LA2 may emit the second light of a green color, the third light emission area LA3 may emit the third light of a blue color, and the fourth light emission area LA4 may emit the second light of a green color.

In an embodiment, each of the light emission areas LA1, LA2, LA3 and LA4 of the display device 10 may be an area in which a light emitting layer EL (see FIG. 10) overlaps pixel electrodes AE1, AE2 and AE3 (see FIG. 10). For example, opening areas OPA1, OPA2 and OPA3 (see FIG. 10) of the pixel defining layer PDL (see FIG. 10) may correspond to the light emission areas LA1, LA2, LA3 and LA4. For example, each of the light emission areas LA1, LA2, LA3 and LA4 may be defined by the plurality of opening areas OPA1, OPA2 and OPA3 of the pixel defining layer PDL (see FIG. 10) of the light emitting element layer EML. The first light emission area LA1 may be defined by the first opening area OPA1 (see FIG. 10), which overlaps the first pixel electrode AE1 (see FIG. 10), of the pixel defining layer PDL (see FIG. 10), the second light emission area LA2 may be defined by the second opening area OPA2 (see FIG. 10), which overlaps the second pixel electrode AE2 (see FIG. 10), of the pixel defining layer PDL (see FIG. 10), and the third light emission area LA3 may be defined by the third opening area OPA3 (see FIG. 10), which overlaps the third pixel electrode AE3 (see FIG. 10), of the pixel defining layer PDL (see FIG. 10). The fourth light emission area LA4 may be defined by a fourth opening area, which overlaps the fourth pixel electrode of the pixel defining layer PDL (see FIG. 10).

The plurality of light emission areas LA1, LA2, LA3 and LA4 may be disposed in a PENTILE™ type, where PENTILE™ is an arrangement of luminous areas manufactured by SAMSUNG, for example, a diamond PENTILE™ type. For example, the first light emission area LA1 and the third light emission area LA3 may be spaced apart from each other in the second direction DR2, and may be alternately disposed in the first and second directions DR1 and DR2. The second light emission area LA2 and the fourth light emission area LA4 may be spaced apart from each other in the first and second directions DR1 and DR2, and the first and third light emission areas LA1 and LA3 adjacent to each other may be spaced apart from each other in the fourth or fifth direction DR4 or DR5. The second light emission area LA2 and the fourth light emission area LA4 may be repeatedly disposed along the first and second directions DR1 and DR2, and the second and first light emission areas LA2 and LA1 or the fourth and third light emission areas LA4 and LA3 may be alternately disposed along the fourth or fifth direction DR4 or DR5.

In a first diagonal column C1, the first light emission area LA1 and the fourth light emission area LA4 of the first pixel PX1 and the first light emission area LA1 and the fourth light emission area LA4 of the second pixel PX2 may be disposed in the fifth direction DR5. In a second diagonal column C2, the second light emission area LA2 and the third light emission area LA3 of the first pixel PX1 and the second light emission area LA2 and the third light emission area LA3 of the second pixel PX2 may be disposed in the fifth direction DR5. In a third diagonal column C3, the first light emission area LA1 and the fourth light emission area LA4 of the fourth pixel PX4 and the first light emission area LA1 and the fourth light emission area LA4 of the third pixel PX3 may be disposed in the fifth direction DR5. In a fourth diagonal column C4, the second light emission area LA2 and the third light emission area LA3 of the fourth pixel PX4 and the second light emission area LA2 and the third light emission area LA3 of the third pixel PX3 may be disposed in the fifth direction DR5.

In a first diagonal row R1, the first light emission area LA1 and the second light emission area LA2 of the first pixel PX1 and the first light emission area LA1 and the second light emission area LA2 of the fourth pixel PX4 may be disposed in the fourth direction DR4. In a second diagonal row R2, the fourth light emission area LA4 and the third light emission area LA3 of the first pixel PX1 and the fourth light emission area LA4 and the third light emission area LA3 of the fourth pixel PX4 may be disposed in the fourth direction DR4. In a third diagonal row R3, the first light emission area LA1 and the second light emission area LA2 of the second pixel PX2 and the first light emission area LA1 and the second light emission area LA2 of the third pixel PX3 may be disposed in the fourth direction DR4. In a fourth diagonal row R4, the fourth light emission area LA4 and the third light emission area LA3 of the second pixel PX2 and the fourth light emission area LA4 and the third light emission area LA3 of the third pixel PX3 may be disposed in the fourth direction DR4.

In an embodiment, the first to fourth light emission areas LA1, LA2, LA3 and LA4 may have different areas or sizes. In the embodiment of FIG. 4, the size of the third light emission area LA3 may be greater than the sizes of the first light emission area LA1, the second light emission area LA2 and the fourth light emission area LA4, and the size of the first light emission area LA1 may be greater than the sizes of the second light emission area LA2 and the fourth light emission area LA4. The intensity of the emitted light may vary depending on the size of each light emission area LA1, LA2, LA3 or LA4, and a color of a screen displayed by the display device 10 or the electronic device 1 may be controlled by adjusting the size of each light emission area LA1, LA2, LA3 or LA4. In the embodiment of FIG. 4, the size of the third light emission area LA3 is the largest, but the present disclosure is not necessarily limited thereto. The sizes and areas of the light emission areas LA1, LA2, LA3 and LA4 may be freely adjusted depending on the color of the screen required by the display device 10 and the electronic device 1. In addition, the size of each of the light emission areas LA1, LA2, LA3 and LA4 may be related to light efficiency, lifespan of the light emitting element ED and the like, and may be in a trade-off relation with reflection by external light. The size of each of the light emission areas LA1, LA2, LA3 and LA4 may be adjusted in consideration of the above details.

A touch electrode TL may be disposed between the light emission areas LA1, LA2, LA3 and LA4. The touch electrode TL may extend in the fourth direction DR4 and the fifth direction DR5, and may be spaced apart from the light emission areas LA1, LA2, LA3 and LA4. The touch electrode TL may overlap the pixel defining layer PDL and a second light blocking layer BM2. Although the touch electrode TL is briefly shown, the touch electrode TL may include a touch driving electrode and a sensing electrode.

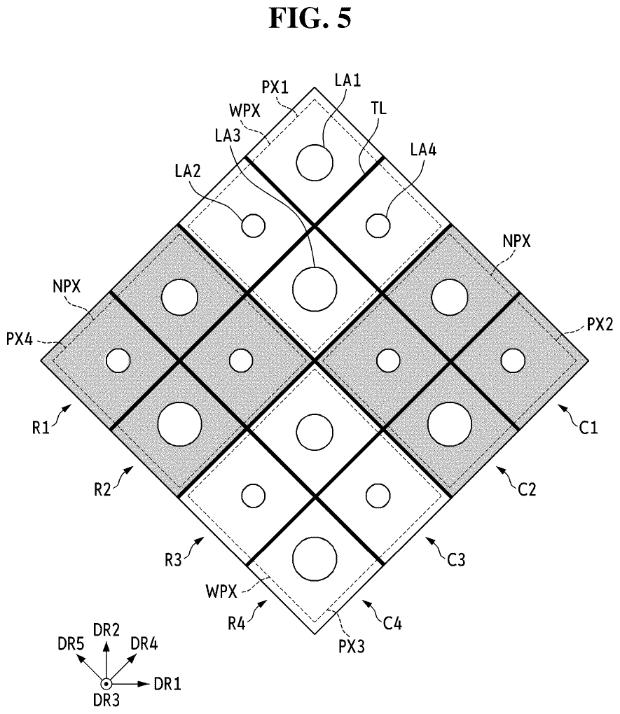

FIG. 5 is a plan view illustrating a light emitting pixel depending on a light emitting mode of a display device according to an embodiment.

Referring to FIG. 5, the display device 10 may include a first type pixel such as the first pixel PX1 and the third pixel PX3 and a second type pixel such as the second pixel PX2 and the fourth pixel PX4. For example, the first type pixel may be a normal mode pixel WPX, and the second type pixel may be a privacy mode pixel NPX.

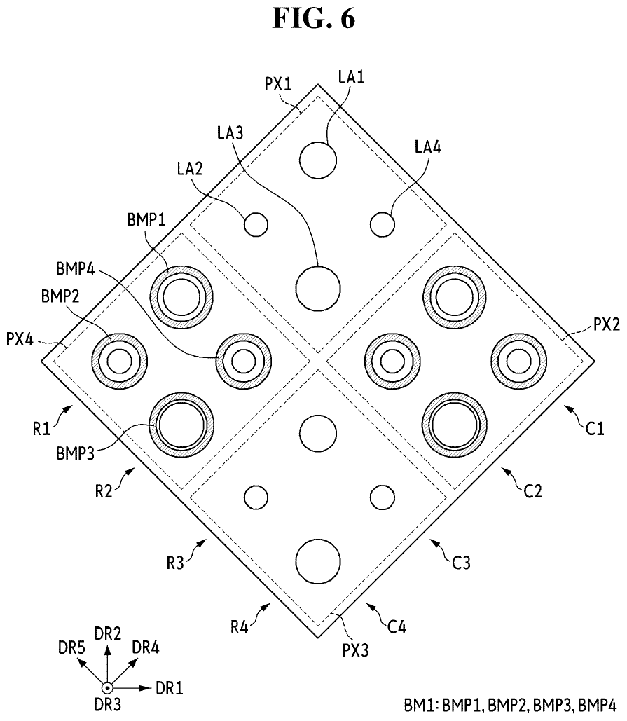

The first type pixel and the second type pixel may be classified depending on whether a first light blocking layer BM1 (see FIG. 6), which will be described later, is disposed. For example, the first light blocking layer BM1 (see FIG. 6) might not be disposed in the first pixel PX1 and the third pixel PX3, and may be disposed in the second pixel PX2 and the fourth pixel PX4. The first light blocking layer BM1 (see FIG. 6) will be described later with reference to FIG. 6.

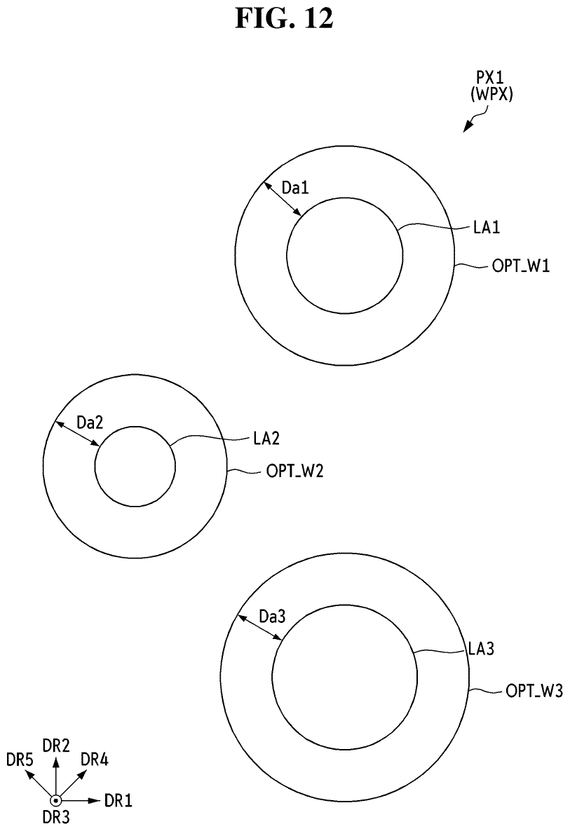

Furthermore, the first type pixel and the second type pixel may be classified depending on a distance between the light emission areas LA1, LA2, LA3 and LA4 and light blocking patterns BMP1, BMP2, BMP3 and BMP4 (see FIG. 6) of the first light blocking layer BM1 (see FIG. 6). This will be described later with reference to FIG. 12.

The display device 10, according to an embodiment, may include the first type pixel and the second type pixel, thereby adjusting side visibility depending on the light emitting mode. The light blocking patterns of the first light blocking layer BM1 may partially cover the light emission areas LA1, LA2, LA3 and LA4 depending on a viewing angle of the display device 10, and may block emission of light at a specific viewing angle.

For example, in a first light emitting mode (e.g., a normal mode) of the display device 10, in which there is no limitation in side visibility (e.g., visibility from wide angles), both the first type pixel and the second type pixel may emit light. For example, when all of the first to fourth pixels PX1, PX2, PX3 and PX4 emit light in the first light emitting mode, light emitted from at least the first pixel PX1 and the third pixel PX3 may be visually recognized by a user no matter which direction the display device 10 is viewed.

In a second light emitting mode (e.g., a privacy mode) of the display device 10, in which limitation in side visibility is required, only the second type pixel may emit light. For example, as shown in FIG. 5, when only the second pixel PX2 and the fourth pixel PX4 emit light in the second light emitting mode, light may be blocked by the light blocking patterns BMP1, BMP2, BMP3 and BMP4 (see FIG. 6) of the first light blocking layer BM1 at a specific viewing angle. Since the first pixel PX1 and the third pixel PX3 do not emit light, in the second light emitting mode of the display device 10, the screen may be visually recognized only by a user who views the display device 10 from the front of the display area DA (e.g., form a direct angle), and might not be visually recognized by a user who views the display device 10 from a specific viewing angle or a side of the display area DA. Therefore, the display device 10 may provide a privacy protection mode to a user in that other people standing around the device might not be able to recognize the image that is recognizable to the intended user.

In addition, in the display device 10, as the light blocking patterns BMP1, BMP2, BMP3 and BMP4 (see FIG. 6) of the first light blocking layer BM1 correspond to the light emission areas LA1, LA2, LA3 and LA4 of the second type pixel and thus not to permit light to leak to an adjacent pixel, for example, the first type pixel, thereby not covering the light emission areas LA1, LA2, LA3 and LA4 of the first type pixel in the first light emitting mode. For example, a pixel structure of the display device 10 may be freely disposed and designed even in the case that a display device of high resolution is implemented.

FIG. 6 is a plan view illustrating a light emission area and a first light blocking layer in a display area of a display device according to an embodiment.

Referring to FIG. 6, the display device 10 may include a first light blocking layer BM1. The first light blocking layer BM1 may be disposed in some of the plurality of pixels PX1, PX2, PX3 and PX4 of the display area DA. For example, the first light blocking layer BM1 may be disposed in the second type pixel, for example, the second pixel PX2 and the fourth pixel PX4, among the plurality of pixels PX1, PX2, PX3 and PX4.

In some embodiments, the first light blocking layer BM1 may include a plurality of light blocking patterns BMP1, BMP2, BMP3 and BMP4. The plurality of light blocking patterns BMP1, BMP2, BMP3 and BMP4 might not overlap the first type pixel including the first pixel PX1 and the third pixel PX3, and may overlap the second type pixel including the second pixel PX2 and the fourth pixel PX4.

The plurality of light blocking patterns BMP1, BMP2, BMP3 and BMP4 may include a first light blocking pattern BMP1, a second light blocking pattern BMP2, a third light blocking pattern BMP3 and a fourth light blocking pattern BMP4. The plurality of light blocking patterns BMP1, BMP2, BMP3 and BMP4 may correspond to the plurality of light emission areas LA1, LA2, LA3 and LA4, respectively. For example, the first light blocking pattern BMP1 may surround the first light emission area LA1, the second light blocking pattern BMP2 may surround the second light emission area LA2, the third light blocking pattern BMP3 may surround the third light emission area LA3, and the fourth light blocking pattern BMP4 may surround the fourth light emission area LA4.

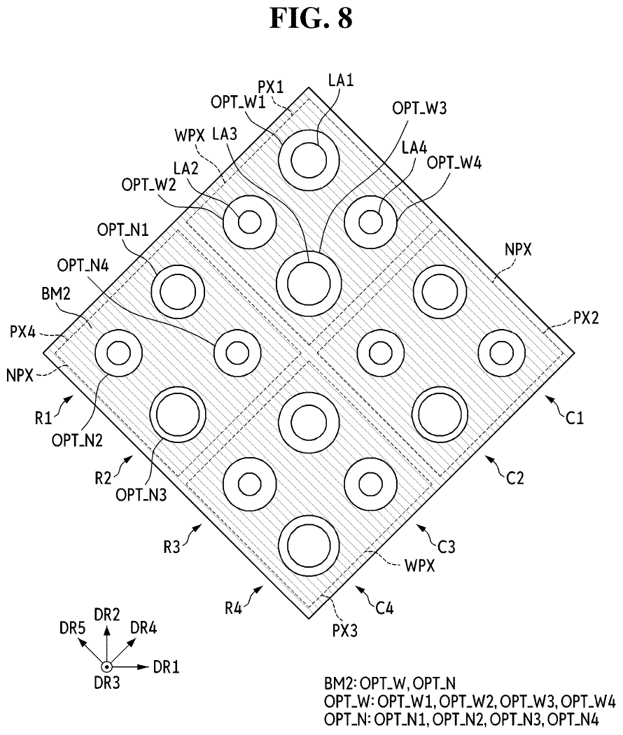

Each of the plurality of light blocking patterns BMP1, BMP2, BMP3 and BMP4 may have an annular shape (e.g., a ring shape or a donut shape), which surrounds the plurality of light emission areas LA1, LA2, LA3 and LA4. Inner sides of the plurality of light blocking patterns BMP1, BMP2, BMP3 and BMP4 may be spaced apart from a boundary of the plurality of light emission areas LA1, LA2, LA3 and LA4 on a plane. For example, the inner sides of the plurality of light blocking patterns BMP1, BMP2, BMP3 and BMP4 may be spaced apart from inner sides of the plurality of opening areas OPA1, OPA2 and OPA3 of the pixel defining layer PDL (see FIG. 8), respectively, on a plane.

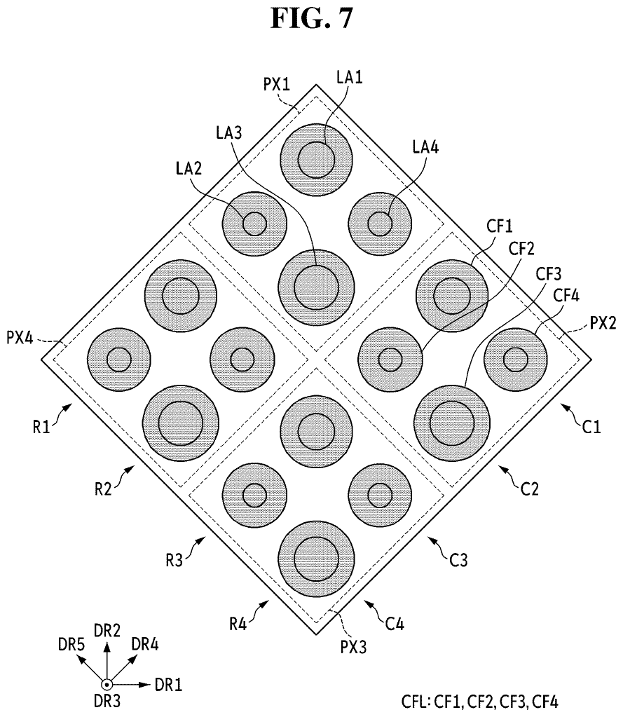

FIG. 7 is a plan view illustrating a light emission area and a color filter layer in a display area of a display device according to an embodiment.

Referring to FIG. 7, the display device 10 may include a color filter layer CFL. The color filter layer CFL may be disposed on the first light blocking layer BM1, but is not necessarily limited thereto. The color filter layer CFL may be disposed on the second light blocking layer BM2. The color filter layer CFL may include a plurality of color filters CF1, CF2, CF3 and CF4.

Each of the plurality of color filters CF1, CF2, CF3 and CF4 may correspond to the plurality of light emission areas LA1, LA2, LA3 and LA4. For example, the plurality of color filters CF1, CF2, CF3 and CF4 may correspond to a plurality of holes OPT_W and OPT_N (see FIG. 8) of the second light blocking layer BM2 (see FIG. 8), which will be described later. The plurality of holes OPT_W and OPT_N (see FIG. 8) of the second light blocking layer BM2 (see FIG. 8) may overlap the plurality of opening areas OPA1, OPA2 and OPA3 (see FIG. 10) of the pixel defining layer PDL (see FIG. 10), and may form a light emission area through which light emitted from the light emission areas LA1, LA2, LA3 and LA4 is emitted. Each of the plurality of color filters CF1, CF2, CF3 and CF4 may have a size larger than that of the plurality of holes OPT_W and OPT_N (see FIG. 8) of the second light blocking layer BM2 (see FIG. 8), and each of the plurality of color filters CF1, CF2, CF3 and CF4 may completely cover the light emission area formed by the plurality of holes OPT_W and OPT_N (see FIG. 8) of the second light blocking layer BM2 (see FIG. 8). Each of the plurality of color filters CF1, CF2, CF3 and CF4 may completely overlap the plurality of holes OPT_W and OPT_N (see FIG. 8) of the second light blocking layer BM2 (see FIG. 8). However, in some embodiments, the color filters CF1, CF2, CF3 and CF4 may be omitted.

The color filters CF1, CF2, CF3 and CF4 may include a first color filter CF1, a second color filter CF2, a third color filter CF3 and a fourth color filter CF4, which correspond to different light emission areas LA1, LA2, LA3 and LA4, respectively. The color filters CF1, CF2, CF3 and CF4 may include a colorant such as a dye or a pigment, which absorbs light of different wavelength bands other than light of a specific wavelength band, and may correspond to a color of light emitted by the light emitting elements including the light emission areas LA1, LA2, LA3 and LA4. For example, the first color filter CF1 may be a red color filter overlapping the first light emission area LA1 and transmit only the first light of a red color. The second color filter CF2 may be a green color filter overlapping the second light emission area LA2 and transmit only the second light of a green color, the third color filter CF3 may be a blue color filter overlapping the third light emission area LA3 and transmit only the third light of a blue color, and the fourth color filter CF4 may be a green color filter overlapping the fourth light emission area LA4 and transmit only the second light of a green color.

Similarly to the arrangement of the light emission areas LA1, LA2, LA3 and LA4, the color filters CF1, CF2, CF3 and CF4 may be disposed in a PENTILE™ type, for example, a diamond PENTILE™ type. For example, the first color filter CF1 and the third color filter CF3 may be alternately disposed in the first and second directions DR1 and DR2. The second color filter CF2 and the fourth color filter CF4 may be disposed in the first and second directions DR1 and DR2, and the first and third color filters CF1 and CF3 adjacent to each other may be disposed in the fourth or fifth direction DR4 or DR5. The second color filter CF2 and the fourth color filter CF4 may be repeatedly disposed along the first and second directions DR1 and DR2, and the second and first color filters CF2 and CF1 or the fourth and third color filters CF4 and CF3 may be alternately disposed along the fourth direction DR4.

According to an embodiment, the plurality of color filters CF1, CF2, CF3 and CF4 may have different planar sizes or areas. As described above, the plurality of light emission areas LA1, LA2, LA3 and LA4 may have different planar sizes or areas, and accordingly, the plurality of color filters CF1, CF2, CF3 and CF4 may have different planar sizes or areas. For example, the size or area of the first color filter CF1, which is a red color filter, may be larger than the size or area of the second color filter CF2 and the fourth color filter CF4, which are green color filters, and the size or area of the third color filter CF3 that is a blue color filter. Also, the size or area of the third color filter CF3 may be larger than the size or area of the second color filter CF2 and the fourth color filter CF4.

In some embodiments, a planar size or area of each of the color filters CF1, CF2 and CF3 disposed in the first pixel PX1 may be the same as a planar size or area of each of the color filters CF1, CF2 and CF3 disposed in the second pixel PX2. For example, the planar size or area of the first color filter CF1 disposed in the first pixel PX1 may be the same as the planar size or area of the first color filter CF1 disposed in the second pixel PX2, the planar size or area of the second color filter CF2 disposed in the first pixel PX1 may be the same as the planar size or area of the second color filter CF2 disposed in the second pixel PX2, and the planar size or area of the third color filter CF3 disposed in the first pixel PX1 may be the same as the planar size or area of the third color filter CF3 disposed in the second pixel PX2, but the present disclosure is not necessarily limited thereto. In some embodiments, the planar size or area of each of the color filters CF1, CF2 and CF3 disposed in the first pixel PX1 may be larger or smaller than the planar size or area of each of the color filters CF1, CF2 and CF3 disposed in the second pixel PX2.

A planar shape of the plurality of color filters CF1, CF2, CF3 and CF4 may be circular similar to that of the light emission areas LA1, LA2, LA3 and LA4, but the present disclosure is not necessarily limited thereto. The planar shape of the color filters CF1, CF2, CF3 and CF4 may be rectangular or rhombus.

FIG. 8 is a plan view illustrating a light emission area and a second light blocking layer in a display area of a display device according to an embodiment.

Referring to FIG. 8, the display device 10 may include a second light blocking layer BM2. The second light blocking layer BM2 may be disposed on the first light blocking layer BM1. In an embodiment, the second light blocking layer BM2 may be disposed on the color filter layer CFL, but is not necessarily limited thereto. When the color filter layer CFL is disposed on the second light blocking layer BM2, the second light blocking layer BM2 may be disposed between the first light blocking layer BM1 and the color filter layer CFL.

The second light blocking layer BM2 may be disposed over the entire surface of the display area DA. The second light blocking layer BM2 may include a plurality of holes OPT_W and OPT_N corresponding to the plurality of light emission areas LA1, LA2, LA3 and LA4, respectively. Alternatively, the plurality of holes OPT_W and OPT_N of the second light blocking layer BM2 may correspond to the plurality of opening areas OPA1, OPA2 and OPA_3 of the pixel defining layer PDL, respectively. The second light blocking layer BM2 may cover the display area DA except for an area in which the plurality of holes OPT_W and OPT_N are disposed in the display area DA. The plurality of holes OPT_W and OPT_N of the second light blocking layer BM2 may be areas in which light emitted from the light emitting element corresponding to each of the light emission areas LA1, LA2, LA3 and LA4 is emitted.

The plurality of holes OPT_W and OPT_N may include a first group hole OPT_W that overlaps the plurality of light emission areas LA1, LA2, LA3 and LA4 of the normal mode pixel WPX, and a second group hole OPT_N that overlaps the plurality of light emission areas LA1, LA2, LA3 and LA4 of the privacy mode pixel NPX. For example, the first group hole OPT_W may overlap the plurality of light emission areas LA1, LA2, LA3 and LA4 of the first pixel PX1 and the third pixel PX3, and the second group hole OPT_N may overlap the plurality of light emission areas LA1, LA2, LA3 and LA4 of the second pixel PX2 and the fourth pixel PX4.

The first group hole OPT_W may include a first hole OPT_W1 that overlaps the first light emission area LA1 of the normal mode pixel WPX, a second hole OPT_W2 that overlaps the second light emission area LA2 of the normal mode pixel WPX, a third hole OPT_W3 that overlaps the third light emission area LA3 of the normal mode pixel WPX, and a fourth hole OPT_W4 that overlaps the fourth light emission area LA4 of the normal mode pixel WPX.

The second group hole OPT_N may include a fifth hole OPT_N1 that overlaps the first light emission area LA1 of the privacy mode pixel NPX, a sixth hole OPT_N2 that overlaps the second light emission area LA2 of the privacy mode pixel NPX, a seventh hole OPT_N3 that overlaps the third light emission area LA3 of the privacy mode pixel NPX, and an eighth hole OPT_N4 that overlaps the fourth light emission area LA4 of the privacy mode pixel NPX.

Each of the plurality of holes OPT_W and OPT_N may have a planar area that is larger than that of each of the light emission areas LA1, LA2, LA3 and LA4. For example, the first and fifth holes OPT_W1 and OPT_N1 may have a planar area that is larger than that of the first light emission area LA1, the second and sixth holes OPT_W2 and OPT_N2 may have a planar area that is larger than that of the second light emission area LA2, and the third and seventh holes

OPT_W3 and OPT_N3 may have a planar area that is larger than that of the third light emission area LA3, and the fourth and eighth holes OPT_W4 and OPT_N4 may have a planar area that is larger than that of the fourth light emission area LA4.

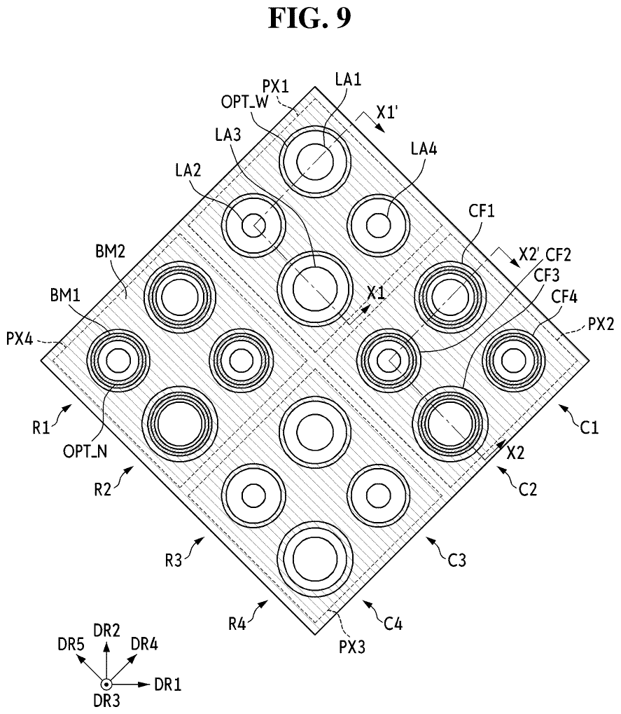

FIG. 9 is a plan view illustrating a light emission area, a first light blocking layer, a color filter layer and a second light blocking layer in a display area of a display device according to an embodiment.

Referring to FIG. 9, in the first pixel PX1 and the third pixel PX3, the size of the first group hole OPT_W may be larger than the size of the light emission areas LA1, LA2 and LA3 on a plane. The sizes of the color filters CF1, CF2 and CF3 may be larger than the size of the first group hole OPT_W on the plane.

In the second pixel PX2 and the fourth pixel PX4, a size of the inner side of the first light blocking layer BM1 may be larger than the size of the light emission areas LA1, LA2 and LA3 on the plane. The size of the second group hole OPT_N may be larger than the size of the inner side of the first light blocking layer BM1 on the plane. A size of an outer side of the first light blocking layer BM1 may be larger than the size of the second group hole OPT_N on the plane. The size of the color filters CF1, CF2 and CF3 may be larger than the size of the outer side of the first light blocking layer BM1 on the plane.

Although the first light blocking layer BM1 is shown as having the size of the inner side, which is smaller than the size of the second group hole OPT_N on the plane, the present disclosure is not necessarily limited thereto. For example, in an embodiment, the size of the inner side of the first light blocking layer BM1 may be larger than the size of the second group hole OPT_N on the plane. Hereinafter, for convenience of description, the case that the size of the inner side of the first light blocking layer BM1 is smaller than the size of the second group hole OPT_N on the plane will be described by way of example, but the present disclosure is not necessarily limited thereto.

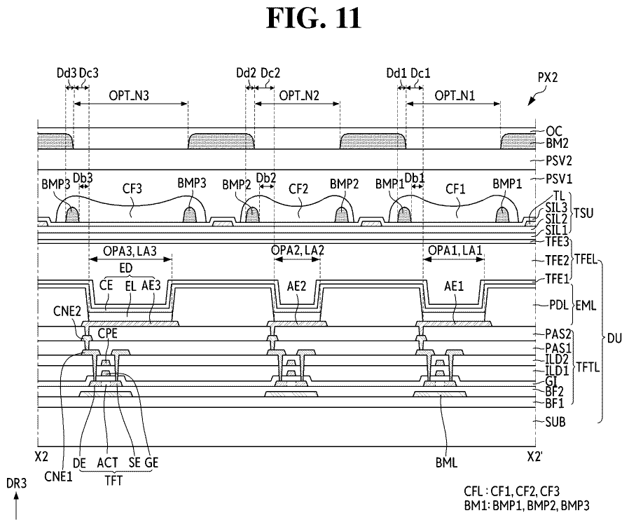

FIG. 10 is a cross-sectional view taken along line X1-X1′ of FIG. 9. FIG. 11 is a cross-sectional view taken along line X2-X2′ of FIG. 9. FIG. 10 shows a cross-section of the first pixel PX1 crossing the first to third light emission areas LA1, LA2 and LA3 as a first type pixel, and FIG. 11 shows a cross-section of the second pixel PX2 crossing the first to third light emission areas LA1, LA2 and LA3 as a second type pixel. In FIGS. 10 and 11, the fourth light emission area LA4 of each type pixel has the same structure as the second light emission area LA2 and thus has been omitted.

Referring to FIGS. 10 and 11 in addition to FIG. 9, the display panel 100 of the display device 10 may include a display layer DU, a touch sensing layer TSU, a first light blocking layer BM1, a color filter layer CFL, passivation layers PSV1 and PSV2, a second light blocking layer BM2 and an overcoat layer OC. The display layer DU may include a substrate SUB, a thin film transistor layer TFTL, a light emitting element layer EML and an encapsulation layer TFEL.

The substrate SUB may be a base substrate or a base. The substrate SUB may be a flexible substrate capable of being subjected to bending, folding, rolling or the like, to a noticeable extent without cracking or otherwise sustaining damage. For example, the substrate SUB may include a polymer resin such as polyimide (PI), but is not necessarily limited thereto. For example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing permeation of the air or moisture. For example, the first buffer layer BF1 may include a plurality of inorganic layers that are alternately stacked.

The lower metal layer BML may be disposed on the first buffer layer BF1. For example, the lower metal layer BML may include a single layer or multi-layer including molybdenum (Mo), aluminum (Al), chromium (Cr), gold (Au), titanium (Ti), nickel (Ni), neodymium (Nd) and copper (Cu), and/or their alloy.

The second buffer layer BF2 may cover the first buffer layer BF1 and the lower metal layer BML. The second buffer layer BF2 may include an inorganic layer capable of preventing permeation of the air or moisture. For example, the second buffer layer BF2 may include a plurality of inorganic layers that are alternately stacked.

The thin film transistor TFT may be disposed on the second buffer layer BF2, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. A portion of the semiconductor layer ACT may be conductorized to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the semiconductor layer ACT and the second buffer layer BF2, and may insulate the semiconductor layer ACT from the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT with the second connection electrode CNE2. The first connection electrode CNE1 may be inserted into the contact holes formed in the second interlayer insulating layer ILD2, the first interlayer insulating layer ILD1 and the gate insulating layer GI to contact the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to the pixel electrodes AE1, AE2 and AE3 of the light emitting element ED. The second connection electrode CNE2 may be inserted into a contact hole formed in the first passivation layer PAS1 to contact the first connection electrode CNE1.

The second passivation layer PAS2 may cover the second connection electrode CNE2 and the first passivation layer PAS1. The second passivation layer PAS2 may include a contact hole through which the pixel electrodes AE1, AE2 and AE3 of the light emitting element ED pass.

The light emitting element layer EML may be disposed on the thin film transistor layer TFTL. The light emitting element layer EML may include a light emitting element ED and a pixel defining layer PDL. The light emitting element ED may include pixel electrodes AE1, AE2 and AE3, a light emitting layer EL and a common electrode CE.

The pixel electrodes AE1, AE2 and AE3 may be disposed on the second passivation layer PAS2. Each of the pixel electrodes AE1, AE2 and AE3, which are different from one another, may overlap any one of the different opening areas OPA1, OPA2 and OPA3 of the pixel defining layer PDL. The pixel electrodes AE1, AE2 and AE3 may be electrically connected to the drain electrode DE of the thin film transistor TFT through the first and second connection electrodes CNE1 and CNE2.

The light emitting layer EL may be disposed on the pixel electrodes AE1, AE2 and AE3. For example, the light emitting layer EL may be an organic light emitting layer including an organic material, but is not necessarily limited thereto. When the light emitting layer EL corresponds to the organic light emitting layer, the thin film transistor TFT applies a predetermined voltage to the pixel electrodes AE1, AE2 and AE3 of the light emitting element ED and the common electrode CE of the light emitting element ED receives a common voltage or a cathode voltage, holes and electrons may move to the light emitting layer EL through a hole transporting layer and an electron transporting layer, respectively, and may be combined with each other in the light emitting layer EL that is configured to emit light.

In an embodiment, the light emitting layers EL respectively disposed on the different pixel electrodes AE1, AE2 and AE3 may emit light of different colors. For example, the light emitting layer disposed on the first pixel electrode AE1 may emit red light of a first color, the light emitting layer disposed on the second pixel electrode AE2 may emit green light of a second color, and the light emitting layer disposed on the third pixel electrode AE3 may emit blue light of a third color, but the present disclosure is not necessarily limited thereto. In an embodiment, the light emitting layer EL may be disposed as one layer in common on the different pixel electrodes AE1, AE2 and AE3 and the pixel defining layer PDL, or the light emitting layers EL disposed on the different pixel electrodes AE1, AE2 and AE3 may emit light of the same color. In this case, the display device 10 may further include a color adjustment layer disposed on the light emitting elements ED.

The common electrode CE may be disposed on the light emitting layer EL. For example, the common electrode CE may be implemented in the form of an electrode that is not divided for each of a plurality of pixels and is common to all of the pixels. The common electrode CE may be disposed on the light emitting layer EL in the pixel electrodes AE1, AE2 and AE3, and may be disposed on the pixel defining layer PDL in an area other than the pixel electrodes AE1, AE2 and AE3.

The common electrode CE may receive a common voltage or a low potential voltage. When the pixel electrodes AE1, AE2 and AE3 receive a voltage corresponding to the data voltage and the common electrode CE receives the low potential voltage, a potential difference is formed between the pixel electrodes AE1, AE2 and AE3 and the common electrode CE, whereby the light emitting layer EL may emit light.

The pixel defining layer PDL may include a plurality of opening areas OPA1, OPA2 and OPA3, and thus may be disposed on a portion of the pixel electrodes AE1, AE2 and AE3 and the second passivation layer PAS2. Each of the opening areas OPA1, OPA2 and OPA3 of the pixel defining layer PDL may expose a portion of the pixel electrodes AE1, AE2 and AE3. As described above, each of the opening areas OPA1, OPA2 and OPA3 of the pixel defining layer PDL may define the first to third light emission areas LA1, LA2 and LA3, and may have different areas or sizes. The pixel defining layer PDL may separate and insulate the pixel electrodes AE1, AE2 and AE3 of the plurality of light emitting elements ED from one another.

The pixel defining layer PDL may include a light absorbing material to prevent light reflection. For example, the pixel defining layer PDL may include a polyimide (PI)-based binder and a pigment in which red, green and blue are mixed. Alternatively, the pixel defining layer PDL may include a cardo-based binder resin, and a mixture of a lactam black pigment and a blue pigment. Alternatively, the pixel defining layer PDL may include carbon black.

The encapsulation layer TFEL may be disposed on the common electrode CE to cover the plurality of light emitting elements ED. The encapsulation layer TFEL may include at least one inorganic layer to prevent oxygen or moisture from being permeated into the light emitting element layer EML. The encapsulation layer TFEL may include at least one organic layer to protect the light emitting element layer EML from particles such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon nitride and/or silicon oxynitride.

The second encapsulation layer TFE2 may include a polymer-based material. The polymer-based material may include an acrylic resin, an epoxy resin, polyimide, and polyethylene. For example, the second encapsulation layer TFE2 may include an acrylic resin, for example, polymethylmethacrylate, polyacrylic acid and the like. The second encapsulation layer TFE2 may be formed by curing a monomer or coating a polymer.

The touch sensing layer TSU may be disposed on the encapsulation layer TFEL. The touch sensing layer TSU may include a first touch insulating layer SILI, a second touch insulating layer SIL2, a touch electrode TL, and a third touch insulating layer SIL3.

The first touch insulating layer SILI may be disposed on the encapsulation layer TFEL. The first touch insulating layer SILI may have insulating and optical functions. The first touch insulating layer SILI may include at least one inorganic layer. Selectively, the first touch insulating layer SIL1 may be omitted.

The second touch insulating layer SIL2 may cover the first touch insulating layer SIL1. A touch electrode of another layer may be further disposed on the first touch insulating layer SIL1, and the second touch insulating layer SIL2 may cover the touch electrode TL. The second touch insulating layer SIL2 may have insulating and optical functions. For example, the second touch insulating layer SIL2 may be an inorganic layer that includes at least one of a silicon nitride layer, a silicon oxynitride layer, a silicon oxide layer, a titanium oxide layer or an aluminum oxide layer.

A portion of the touch electrodes TL may be disposed on the second touch insulating layer SIL2. Each of the touch electrodes TL might not overlap the pixel electrodes AE1, AE2 and AE3. Each of the touch electrodes TL may include a single layer of molybdenum (Mo), titanium (Ti), copper (Cu), aluminum (Al) or indium tin oxide (ITO), or may include a stacked structure (Ti/Al/Ti) of aluminum and titanium, a stacked structure (ITO/Al/ITO) of aluminum and ITO, APC alloy, and a stacked structure (ITO/APC/ITO) of APC alloy and ITO.

The touch electrode TL of the touch sensing layer TSU may have a predetermined line width and may overlap the second light blocking layer BM2. The second light blocking layer BM2 may have a width sufficient to completely cover the touch electrode TL. In some embodiments, the touch electrode TL may be disposed so that its center is substantially parallel with the center of the second light blocking layer BM2, and an interval from one side of the touch electrode TL to one side of the second light blocking layer BM2 may be substantially the same as an interval from the other side of the touch electrode TL to the other side of the second light blocking layer BM2.

The third touch insulating layer SIL3 may cover the touch electrode TL and the second touch insulating layer SIL2. The third touch insulating layer SIL3 may have insulating and optical functions. The third touch insulating layer SIL3 may include the material exemplified in the second touch insulating layer SIL2.

The first light blocking layer BM1 may be disposed on the third touch insulating layer SIL3 of the touch sensing layer TSU.

The first light blocking layer BM1 might not be disposed in the first type pixel (or the first pixel PX1), but may be disposed only in the second type pixel (or the second pixel PX2). The first light blocking layer BM1 may correspond to the light emission areas LA1, LA2 and LA3 of the second type pixel.

The first light blocking layer BM1 may include a plurality of light blocking patterns BMP1, BMP2 and BMP3. The plurality of light blocking patterns BMP1, BMP2 and BMP3 may include a first light blocking pattern BMP1, a second light blocking pattern BMP2 and a third light blocking pattern BMP3.

The plurality of light blocking patterns BMP1, BMP2 and BMP3 may correspond to the plurality of light emission areas LA1, LA2 and LA3 of the second type pixel, respectively. For example, the first light blocking pattern BMP1 may surround the first light emission area LA1, the second light blocking pattern BMP2 may surround the second light emission area LA2, and the third light blocking pattern BMP3 may surround the third light emission area LA3.

The first light blocking layer BM1 may be disposed on both sides of each of the light emission areas LA1, LA2 and LA3 of the second type pixel on a cross-section. For example, as shown in FIG. 11, the first light blocking pattern BMP1 may be disposed on both sides of the first light emission area LA1 of the second pixel PX2 on a cross-section, the second light blocking pattern BMP2 may be disposed on both sides of the second light emission area LA2 of the second pixel PX2 on a cross-section, and the third light blocking pattern BMP3 may be disposed on both sides of the third light emission area LA3 of the second pixel PX2 on a cross-section.

At least a portion of the first light blocking layer BM1 may overlap the second group hole OPT_N of the second light blocking layer BM2 of the second type pixel. For example, as shown in FIG. 11, at least a portion of the first light blocking pattern BMP1 may overlap the fifth hole OPT_N1 of the second light blocking layer BM2 of the second pixel PX2, at least a portion of the second light blocking pattern BMP2 may overlap the sixth hole OPT_N2 of the second light blocking layer BM2 of the second pixel PX2, and at least a portion of the third light blocking pattern BMP3 may overlap the seventh hole OPT_N3 of the second light blocking layer BM2 of the second pixel PX2.

The first light blocking layer BM1 may include a light absorbing material. For example, the first light blocking layer BM1 may include an inorganic black pigment or an organic black pigment. The inorganic black pigment may be carbon black, and the organic black pigment may include at least one of lactam black, perylene black or aniline black, but is not necessarily limited thereto.

The first light blocking layer BM1 may prevent light leakage to improve WAD characteristics. This will be described later with reference to FIG. 12.

The color filters CF1, CF2 and CF3 of the color filter layer CFL may be disposed on the first light blocking layer BM1. The color filters CF1, CF2 and CF3 may correspond to the light emission areas LA1, LA2 and LA3, respectively. For example, the first color filter CF1 may correspond to the first light emission area LA1, the second color filter CF2 may correspond to the second light emission area LA2, and the third color filter CF3 may correspond to the third light emission area LA3.

In some embodiments, the color filters CF1, CF2 and CF3 of the color filter layer CFL in the second type pixel may cover the first light blocking layer BM1. For example, the first color filter CF1 may cover the first light blocking pattern BMP1, the second color filter CF2 may cover the second light blocking pattern BMP2, and the third color filter CF3 may cover the third light blocking pattern BMP3.

The color filters CF1, CF2 and CF3 of the color filter layer CFL may have widths greater than those of the holes OPT_W and OPT_N of the second light blocking layer BM2. For example, the width of the first color filter CF1 may be greater than the widths of the first hole OPT_W1 and the fifth hole OPT_N1, the width of the second color filter CF2 may be greater than the widths of the second hole OPT_W2 and the sixth hole OPT_N2, and the width of the third color filter CF3 may be greater than the widths of the third hole OPT_W3 and the seventh hole OPT_N3.

The passivation layers PSV1 and PSV2 may be disposed on the first light blocking layer BM1 and the color filter layer CFL. The passivation layers PSV1 and PSV2 may be disposed over the entire surface of the display area DA to planarize the upper surface of the display panel 100. The passivation layers PSV1 and PSV2 may include a first passivation layer PSV1 disposed on the color filter layer CFL and the first light blocking layer BM1, and a second passivation layer PSV2 disposed on the first passivation layer PSV1. The passivation layers PSV1 and PSV2 may include a plurality of layers to planarize a step difference caused by the color filter layer CFL and the first light blocking layer BM1.

The passivation layers PSV1 and PSV2 may be colorless light-transmissive layers that do not have a color of a visible light band. For example, the passivation layers PSV1 and PSV2 may include a colorless light-transmissive organic material such as an acrylic resin.

The second light blocking layer BM2 may be disposed on the passivation layers PSV1 and PSV2.

The second light blocking layer BM2 may include a plurality of holes OPT_W and OPT_N, which overlap a conductive line of the touch electrode TL and overlap the light emission areas LA1, LA2, LA3 and LA4 and the opening areas OPA1, OPA2 and OPA3 of the pixel defining layer PDL. For example, the first hole OPT_W1 may overlap the first light emission area LA1 of the first pixel PX1 and the first opening area OPA1, the second hole OPT_W2 may overlap the second light emission area LA2 of the first pixel PX1 and the second opening area OPA2, and the third hole OPT_W3 may overlap the third light emission area LA3 of the first pixel PX1 and the third opening area OPA3. The fourth hole OPT_W4 (see FIG. 8) may overlap the fourth light emission area LA4 (see FIG. 8) of the first pixel PX1 and the fourth opening area. The fifth hole OPT_N1 may overlap the first light emission area LA1 of the second pixel PX2 and the first opening area OPA1, the sixth hole OPT_N2 may overlap the second light emission area LA2 of the second pixel PX2 and the second opening area OPA2, and the seventh hole OPT_N3 may overlap the third light emission area LA3 of the second pixel PX2 and the third opening area OPA3. The eighth hole OPT_N4 (see FIG. 8) may overlap the fourth light emission area LA4 (see FIG. 8) of the second pixel PX2 and the fourth opening area.

The plurality of holes OPT_W and OPT_N of the second light blocking layer BM2 may correspond to the color filters CF1, CF2 and CF3, respectively. For example, the first hole OPT_W1 and the fifth hole OPT_N1 may correspond to the first color filter CF1, the second hole OPT_W2 and the sixth hole OPT_N2 may correspond to the second color filter CF2, and the third hole OPT_W3 and the seventh hole OPT_N3 may correspond to the third color filter CF3. Each of the color filters CF1, CF2 and CF3 may have an area that is larger than areas of the plurality of holes OPT_W and OPT_N on a plane.

The area or size of each of the holes OPT_W and OPT_N may be larger than the area or size of the light emission areas LA1, LA2 and LA3. Also, the area or size of each of the holes OPT_W and OPT_N may be larger than the opening areas OPA1, OPA2 and OPA3 of the pixel defining layer PDL, and light emitted from the light emitting element ED may be visually recognized by a user not only on the front surface but also on the side of the display device 10.

The second light blocking layer BM2 may include a light absorbing material. For example, the second light blocking layer BM2 may include an inorganic black pigment or an organic black pigment. The inorganic black pigment may be carbon black, and the organic black pigment may include at least one of lactam black, perylene black or aniline black, but the present disclosure is not necessarily limited thereto.

The overcoat layer OC may be disposed on the second light blocking layer BM2 and the passivation layers PSV1 and PSV2. The overcoat layer OC may be disposed over the entire surface of the display area DA to planarize the upper surface of the display panel 100. The overcoat layer OC may be a colorless light-transmissive layer that does not have a color of a visible light band. For example, the overcoat layer OC may include a colorless light-transmissive organic material such as an acrylic resin.

Hereinafter, the relation among the light emission areas LA1, LA2, LA3 and LA4, the first light blocking layer BM1 and the second light blocking layer BM2 in the first type pixel and the second type pixel will be described in more detail with reference to other drawings.

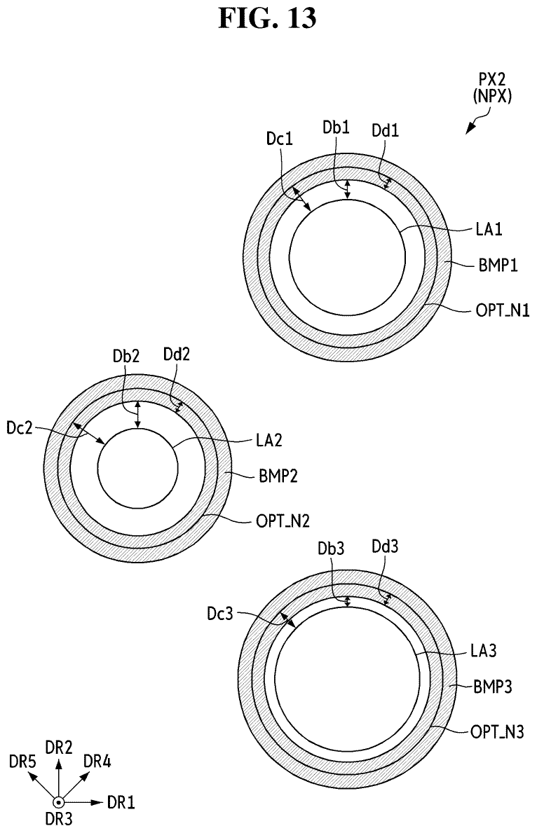

FIG. 12 is a plan view illustrating a first pixel of a display device according to an embodiment. FIG. 13 is a plan view illustrating a second pixel of a display device according to an embodiment.

Referring to FIGS. 12 and 13 in addition to FIGS. 10 and 11, the normal mode pixel WPX and the privacy mode pixel NPX (e.g., the first pixel PX1 and the second pixel PX2) may be different from each other in the presence or absence of the first light blocking layer BM1. Also, the normal mode pixel WPX and the privacy mode pixel NPX may be different from each other in a distance between the light emission areas LA1, LA2 and LA3 and the holes OPT_W and OPT_N of the second light blocking layer BM2.

For example, the first pixel PX1 that is the normal mode pixel WPX might not include the first light blocking layer BM1. The second pixel PX2 that is the privacy mode pixel NPX may include the first light blocking layer BM1.

In the first light emitting mode (e.g., the normal mode), both the first pixel PX1 and the second pixel PX2 may emit light. In this case, when the display device 10 is viewed from any one side, light emitted from the first pixel PX1 may be covered only in the second light blocking layer BM2. Therefore, light may be visually recognized even at a viewing angle of a medium angle or a high angle as compared with the second light emitting mode (e.g., the privacy mode) in which only the second pixel PX2 emits light.

In the second light emitting mode (e.g., the privacy mode), only the second pixel PX2 may emit light, and the first pixel PX1 might not emit light. In this case, when the display device 10 is viewed from any one side, light emitted from the second pixel PX2 may be doubly covered by the light blocking patterns BMP1, BMP2 and BMP3 of the first light blocking layer BM1 and the second light blocking layer BM2. For example, in the second light emitting mode, the display device 10 may control visibility at a specific viewing angle and provide a privacy protection mode to a user as light emits from only the second type pixel, in which both the first light blocking layer BM1 and the second light blocking layer BM2 are disposed, in the second light emission mode.

In the display device 10, according to the present embodiment, each distance between the first group holes OPT_W and the light emission areas LA1, LA2 and LA3 of the first pixel PX1 may be different from each distance between the second group holes OPT_N and the light emission areas LA1, LA2 and LA3 of the second pixel PX2. For example, a distance Da1 between the first hole OPT_W1 and the first light emission area LA1 of the first pixel PX1 may be greater than a distance Dc1 between the fifth hole OPT_N1 and the first light emission area LA1 of the second pixel PX2, a distance Da2 between the second hole OPT_W2 and the second light emission area LA2 of the first pixel PX1 may be greater than a distance Dc2 between the sixth hole OPT_N2 and the second light emission area LA2 of the second pixel PX2, and a distance Da3 between the third hole OPT_W3 and the third light emission area LA3 of the first pixel PX1 may be greater than a distance Dc3 between the seventh hole OPT_N3 and the third light emission area LA3 of the second pixel PX2. Therefore, when the second light emitting mode is driven, a light leakage phenomenon, in which light of a viewing angle of a high angle, which is emitted from the second pixel PX2, is emitted beyond adjacent pixels, may be minimized, whereby a color mixture between the adjacent pixels may be prevented from occurring.

In some embodiments, the distance Da1 between the first hole OPT_W1 and the first light emission area LA1 of the first pixel PX1, the distance Da2 between the second hole OPT_W2 and the second light emission area LA2 of the first pixel PX1 and the distance Da3 between the third hole OPT_W3 and the third light emission area LA3 of the first pixel PX1 may be the same as one another. Therefore, when the first light emitting mode is driven, light that is not blocked by the first light blocking layer BM1 may be prevented from being mixed between the adjacent pixels, and luminance of each pixel may be uniformly maintained at a viewing angle of a low angle, whereby color reproducibility and color uniformity may be increased.

As described above, since the size or area of the first light emission area LA1 may be larger than the size or area of the second light emission area LA2 and may be smaller than the size or area of the third light emission area LA3, the amount of light emission may be large in the order of the third light emission area LA3, the first light emission area LA1 and the second light emission area LA2. Therefore, in order to control light leakage of a viewing angle of a high angle in the display device 10, according to the present embodiment, the distance Dc1 between the fifth hole OPT_N1 and the first light emission area LA1 of the second pixel PX2 may be smaller than the distance Dc2 between the sixth hole OPT_N2 and the second light emission area LA2 of the second pixel PX2, and may be greater than the distance Dc3 between the seventh hole OPT_N3 and the third light emission area LA3 of the second pixel PX2. For example, as the amount of light emission in the light emission areas LA1, LA2 and LA3 is increased, the distance from the second group holes OPT_N through which light is emitted may be reduced, whereby light leakage at a viewing angle of a high angle may be effectively controlled.

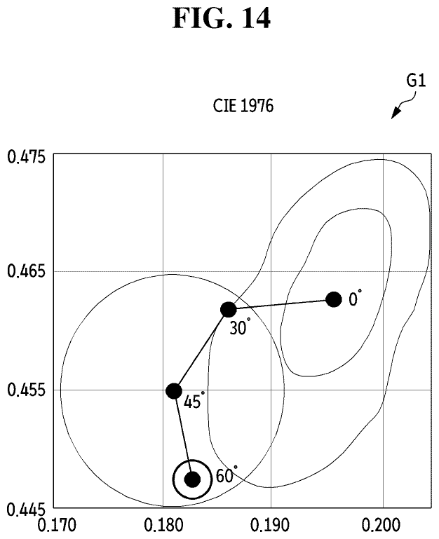

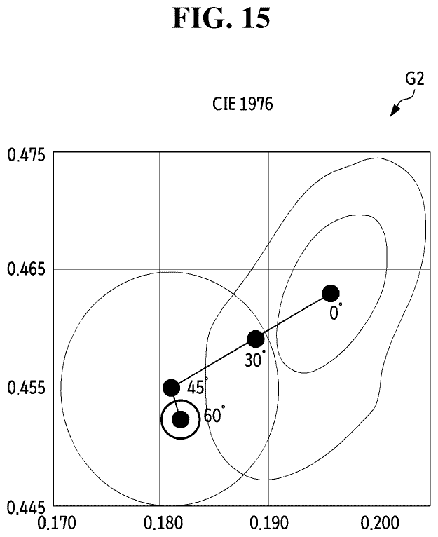

Also, in the display device 10, according to the present embodiment, the distances between the inner sides of the light blocking patterns BMP1, BMP2 and BMP3 and the light emission areas LA1, LA2 and LA3 may be different from one another. For example, a distance Db1 between the inner side of the first light blocking pattern BMP1 and the first light emission area LA1 may be smaller than a distance Db2 between the inner side of the second light blocking pattern BMP2 and the second light emission area LA2, and may be greater than a distance Db3 between the inner side of the third light blocking pattern BMP3 and the third light emission area LA3. As the amount of light emission in the light emission areas LA1, LA2 and LA3 is increased, the distance from the light blocking patterns BMP1, BMP2 and BMP3 that block light may be reduced, whereby WAD characteristics of the display device 10 may be improved. This will be described later with reference to FIGS. 14 and 15.

In some embodiments, a distance Dd1 between the inner side of the first light blocking pattern BMP1 and the inner side of the fifth hole OPT_N1, a distance Dd2 between the inner side of the second light blocking pattern BMP2 and the inner side of the sixth hole OPT_N2 and a distance Dd3 between the inner side of the third light blocking pattern BMP3 and the inner side of the seventh hole OPT_N3 may be the same as one another. Therefore, when the second light emitting mode is driven, luminance of each pixel may be uniformly maintained at a viewing angle of a low angle, whereby color reproducibility and color uniformity may be increased.

Hereinafter, the effects for improving WAD characteristics of the display device 10 will be described with reference to FIGS. 14 and 15.

FIG. 14 is a view illustrating a color coordinate system indicating WAD characteristics of a display device according to a comparative embodiment. FIG. 15 is a view illustrating a color coordinate system indicating WAD characteristics of a display device according to an embodiment.

Referring to FIGS. 14 and 15 in addition to FIGS. 12 and 13, a first graph G1 and a second graph G2 are graphs showing traces of WAD characteristics extracted from a CIE 1976 color coordinate system. The first graph G1 of FIG. 14 indicates WAD characteristics of the display device 10 according to the comparative embodiment, and the second graph G2 of FIG. 15 indicates WAD characteristics of the display device 10 according to an embodiment.

White Angular Difference (WAD) characteristics are items that evaluate changes in white light characteristics according to an observation angle (a viewing angle) of the display device 10, and are indicators that can confirm color characteristics according to the viewing angle.

Each of the first graph G1 and the second graph G2 includes coordinate values of WAD characteristics measured at viewing angles of 0° (front direction), 30°, 45° and 60°, respectively. The x-axis of each of the first graph G1 and the second graph G2 indicates a coordinate u′ of the CIE 1976 color coordinate system, and the y-axis thereof indicates a coordinate v′ of the CIE 1976 color coordinate system.

In the display device 10 according to the present embodiment, the distance Db1 between the inner side of the first light blocking pattern BMP1 and the first light emission area LA1 may be smaller than the distance Db2 between the inner side of the second light blocking pattern BMP2 and the second light emission area LA2, and may be greater than the distance Db3 between the inner side of the third light blocking pattern BMP3 and the third light emission area LA3.

In the display device 10, according to the comparative embodiment, the distance Db1 between the inner side of the first light blocking pattern BMP1 and the first light emission area LA1, the distance Db2 between the inner side of the second light blocking pattern BMP2 and the second light emission area LA2 and the distance Db3 between the inner side of the third light blocking pattern BMP3 and the third light emission area LA3 may all be the same as one another.

In both the display device 10, according to the present embodiment, and the display device 10, according to the comparative embodiment, the size or area of the first light emission area LA1 is smaller than the size or area of the third light emission area LA3, and is larger than the size or area of the second light emission area LA2.

In the display device 10, according to the comparative embodiment, the sizes or areas of the light emission areas LA1, LA2 and LA3 are different from one another, but the distance Db1 between the inner side of the first light blocking pattern BMP1 and the first light emission area LA1, the distance Db2 between the inner side of the second light blocking pattern BMP2 and the second light emission area LA2 and the distance Db3 between the inner side of the third light blocking pattern BMP3 and the third light emission area LA3 are all the same as one another, so that WAD characteristic coordinates are positioned in a relatively downward direction at a viewing angle of 60° of a relatively high angle.

In the display device 10, according to the present embodiment, depending on the sizes or areas of the light emission areas LA1, LA2 and LA3, the distance Db1 between the inner side of the first light blocking pattern BMP1 and the first light emission area LA1 is smaller than the distance Db2 between the inner side of the second light blocking pattern BMP2 and the second light emission area LA2 and is greater than the distance Db3 between the inner side of the third light blocking pattern BMP3 and the third light emission area LA3, so that WAD characteristic coordinates are positioned in a relatively upward direction at a viewing angle of 60° of a relatively high angle.

For example, a distance between the WAD characteristic coordinates at a viewing angle of 60° of the second graph G2 and the WAD characteristic coordinates at a viewing angle of 45° of the second graph G2 is shorter than a distance between the WAD characteristic coordinates at a viewing angle of 60° of the first graph G1 and the WAD characteristic coordinates at a viewing angle of 45° of the first graph G1.

As described above, in the display device 10, according to the present embodiment, depending on the sizes or areas of the light emission areas LA1, LA2 and LA3, the distance Db1 between the inner side of the first light blocking pattern BMP1 and the first light emission area LA1 is smaller than the distance Db2 between the inner side of the second light blocking pattern BMP2 and the second light emission area LA2, and is greater than the distance Db3 between the inner side of the third light blocking pattern BMP3 and the third light emission area LA3, so that the WAD characteristics may be improved at a viewing angle of a high angle.

In concluding the detailed description, those skilled in the art will appreciate that many variations and modifications can be made to the described embodiments without substantially departing from the principles of the present disclosure.

What is claimed is:

1. A display device, comprising:
a display area in which a first pixel and a second pixel are disposed, each of the first pixel and the second pixel including first to third light emission areas;
a first light blocking layer disposed in the display area and corresponding to the second pixel;
a plurality of color filters disposed on the first light blocking layer; and
a second light blocking layer disposed on the plurality of color filters, the second light blocking layer including a plurality of holes respectively overlapping the first to third light emission areas of each of the first pixel and the second pixel,
wherein the first light blocking layer includes first to third light blocking patterns surrounding the first to third light emission areas, respectively.

2. The display device of claim 1, wherein the first light blocking layer is omitted from the first pixel.

3. The display device of claim 1, wherein the plurality of holes of the second light blocking layer include:
first to third holes surrounding the first to third light emission areas of the first pixel, respectively; and
fourth to sixth holes surrounding the first to third light emission areas of the second pixel, respectively.

4. The display device of claim 3, wherein a distance between the fourth hole and the first light emission area of the second pixel is a first distance, a distance between the fifth hole and the second light emission area of the second pixel is a second distance, a distance between the sixth hole and the third light emission area of the second pixel, is a third distance, and each of the first distance, the second distance, and the third distance are different from one another.

5. The display device of claim 4, wherein a planar size of the first light emission area is larger than a planar size of the second light emission area, a planar size of the third light emission area is larger than the planar size of the first light emission area,
wherein the third distance is smaller than the first distance, and
wherein the first distance is smaller than the second distance.

6. The display device of claim 3, wherein a distance between the first light blocking pattern and the first light emission area of the second pixel is a fourth distance, a distance between the second light blocking pattern and the second light emission area of the second pixel is a fifth distance, a distance between the third light blocking pattern and the third light emission area of the second pixel is a sixth distance, and each of the fourth distance, the fifth distance, and the sixth distance are different from one another.

7. The display device of claim 6,
wherein a planar size of the first light emission area is larger than a planar size of the second light emission area, a planar size of the third light emission area is larger than the planar size of the first light emission area,
wherein the sixth distance is smaller than the fourth distance, and
wherein the fourth distance is smaller than the fifth distance.

8. The display device of claim 3, wherein a distance between the first hole and the first light emission area of the first pixel is a seventh distance, a distance between the second hole and the second light emission area of the first pixel is an eight distance, a distance between the third hole and the third light emission area of the first pixel is a ninth distance, and each of the seventh distance, the eight distance, and the ninth distance are the same as one another.

9. The display device of claim 3,
wherein a distance between the first hole and the first light emission area of the first pixel is greater than a distance between the fourth hole and the first light emission area of the second pixel,
wherein a distance between the second hole and the second light emission area of the first pixel is greater than a distance between the fifth hole and the second light emission area of the second pixel, and
wherein a distance between the third hole and the third light emission area of the first pixel is greater than a distance between the sixth hole and the third light emission area of the second pixel.

10. The display device of claim 3, wherein a distance between an inner side of the first light blocking pattern and the fourth hole is a tenth distance, a distance between an inner side of the second light blocking pattern and the fifth hole is an eleventh distance, a distance between an inner side of the third light blocking pattern and the sixth hole is a twelfth distance, and each of the tenth distance, the eleventh distance, and the twelfth distance are the same as one another.

11. The display device of claim 3, wherein at least a portion of the first to third light blocking patterns overlaps the fourth to sixth holes, respectively.

12. The display device of claim 1,
wherein both the first pixel and the second pixel emit light in a first light emitting mode,
wherein the second pixel emits light in a second light emitting mode, and
wherein the first pixel does not emit light in the second light emitting mode.

13. The display device of claim 1, wherein the color filter covers the first light blocking layer.

14. The display device of claim 1, wherein each of the first to third light blocking patterns have a ring shape.

15. A display device, comprising:
a first pixel including first to third light emission areas; and
a second pixel including fourth to sixth light emission areas,
wherein each of the first pixel and the second pixel includes:
a plurality of light emitting elements disposed in the first to sixth light emission areas, respectively;
a color filter layer disposed on the plurality of light emitting elements, the color filter layer including a plurality of color filters covering the first to sixth light emission areas; and
a second light blocking layer disposed on the color filter layer, the second light blocking layer including first to sixth holes that overlap the first to sixth light emission areas, respectively, and
wherein the second pixel further includes a first light blocking layer disposed between the plurality of light emitting elements and the color filter layer, including first to third light blocking patterns surrounding the fourth to sixth light emission areas, respectively.

16. The display device of claim 15, wherein the first light blocking layer is omitted from the first pixel.

17. The display device of claim 15,
wherein a planar size of the first light emission area is larger than a planar size of the second light emission area and a planar size of the third light emission area is larger than the planar size of the first light emission area, and
wherein a planar size of the fourth light emission area is larger than a planar size of the fifth light emission area and a planar size of the sixth light emission area is larger than the planar size of the fourth light emission area.

18. The display device of claim 17,
wherein a distance between the sixth hole and the sixth light emission area is smaller than a distance between the fourth hole and the fourth light emission area, and
wherein a distance between the fourth hole and the fourth light emission area is smaller than a distance between the fifth hole and the fifth light emission area.

19. The display device of claim 17,
wherein a distance between the third light blocking pattern and the sixth light emission area is smaller than a distance between the first light blocking pattern and the fourth light emission area, and
wherein the distance between the first light blocking pattern and the fourth light emission area is smaller than a distance between the second light blocking pattern and the fifth light emission area.

20. The display device of claim 17, wherein a distance between the first hole and the first light emission area is a thirteenth distance, a distance between the second hole and the second light emission area is a fourteenth distance, a distance between the third hole and the third light emission area is a fifteenth distance, and each of the thirteenth distance, the fourteenth distance, and the fifteenth distance are the same as one another.

21. The display device of claim 17,
wherein a distance between the first hole and the first light emission area is greater than a distance between the fourth hole and the fourth light emission area,
wherein a distance between the second hole and the second light emission area is greater than a distance between the fifth hole and the fifth light emission area, and
wherein a distance between the third hole and the third light emission area is greater than a distance between the sixth hole and the sixth light emission area.

22. The display device of claim 17, wherein a distance between an inner side of the first light blocking pattern and the fourth hole is a sixteenth distance, a distance between an inner side of the second light blocking pattern and the fifth hole is a seventeenth distance, a distance between an inner side of the third light blocking pattern and the sixth hole is an eighteenth distance, and each of the sixteenth distance, the seventeenth distance, and the eighteenth distance are the same as one another.

23. An electronic device, comprising:
a housing; and
a display panel disposed on the housing,
wherein the display panel includes:
a display area in which a first pixel and a second pixel are disposed, each of the first pixel and the second pixel including first to third light emission areas;
a first light blocking layer disposed in the display area and corresponding to the second pixel;
a plurality of color filters disposed on the first light blocking layer; and
a second light blocking layer disposed on the plurality of color filters, the second light blocking layer including a plurality of holes respectively overlapping the first to third light emission areas of each of the first pixel and the second pixel,
wherein the first light blocking layer includes first to third light blocking patterns surrounding the first to third light emission areas, respectively.

24. The electronic device of claim 23, further comprising an optical device disposed within the display panel, the optical device configured to emit and/or sense light.

25. The electronic device of claim 24, wherein the optical device is a proximity sensor, an illuminance sensor, a camera, a fingerprint reader, and/or a dot projector.

26. The electronic device of claim 23, wherein the display panel is bendable and the housing includes a hinge mechanism for accommodating the bendable display panel.
